(19) United States
(12) Patent Application Publication
(10) Pub. No.: US 2006/0138587 A1
(43) Pub. Date: Jun. 29, 2006

(54) Semiconductor device and manufacturing method thereof

(75) Inventor: Chee-Hong Choi, Busan-city (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/319,535

(22) Filed: Dec. 29, 2005

(30) Foreign Application Priority Data
Dec. 29, 2004 (KR) 10-2004-0114845

(51) Int. Cl. H01L 29/00

(52) U.S. Cl. 257/528

(57) ABSTRACT

An semiconductor device and a manufacturing method minimizes the inductor area in a high frequency device by forming an inductor with a vertical spiral geometry. Accordingly, the device can be highly integrated. In addition, the inductor area overlapped with various devices on a substrate can be minimized so as to prevent deterioration of the electrical characteristics of the inductor.

### CROSS-REFERENCE TO RELATED APPLICATION

This application claims priority to and the benefit of Korean Patent Application No. 10-2004-0114845 filed in the Korean Intellectual Property Office on Dec. 29, 2004, the entire contents of which are incorporated herein by reference.

### BACKGROUND

(a) Technical Field

The present invention relates to a semiconductor device and a method of manufacturing the same. More particularly, the present invention relates to a semiconductor device that is manufactured to minimize the area occupied by an inductor.

(b) Description of the Related Art

Generally, semiconductor devices such as transistors, inductors, capacitors, and a resistor are used in radio frequency (RF) circuits. The inductor may often be an essential component of a radio frequency (RF) device, but it often occupies a large area therein. In addition, neighboring devices, parasitic capacitance, and parasitic resistance, may limit high frequency characteristics of an inductor in a radio frequency (RF) circuit.

In methods according to the related art, an inductor is typically formed having a planar spiral geometry. That is, a metal layer on the uppermost surface of a substrate is formed by bending on the plane substrate to form the inductor. For example, an inductor may be formed to be a rectangular type, an octagonal type, or a circular type. The various types of inductors may enhance inductance, but each of them occupies a large area in an RF device chip.

A metal layer formed on the uppermost part of a substrate having low resistivity and low capacitance is often used as the spiral turns of the planar spiral inductor and is further connected with a lower metal line. A conventional inductor will hereinafter be described in detail with reference to the accompanying drawings.

FIG. 1 is a top plan view showing a conventional inductor, and FIG. 2 is a cross-sectional view of FIG. 1.

Referring to FIG. 1 and FIG. 2, the conventional inductor includes a first metal line 10 having a spiral-turn structure, a via metal plug 12 formed under an edge of the first metal line 10, and a second metal line 14 connecting with the via metal plug 12.

In the conventional inductor having such a structure as described above, when alternating current flows therein, a magnetic field is formed due to Fleming's law.

However, the inductor has a planar structure, and occupies a large area in a chip of a high frequency circuit. Accordingly, the high frequency circuit may have a difficulty in higher integration.

In addition, the large area of the inductor may cause a rise of parasitic capacitance, so the electrical characteristics of the inductor and the reliability of the high frequency device may deteriorate.

In addition, in order to form an inductor having a high inductance, the thickness of the first metal line 10 should be increased. However, the first metal line 10 may be used for different devices in the same chip, so it is difficult to increase the thickness thereof.

The above information disclosed in this Background section is only for enhancement of understanding of the background of the invention and therefore it may contain information that does not form the prior art that is already known in this country to a person of ordinary skill in the art.

### SUMMARY

Consistent with the present invention, there is provided a semiconductor device and a manufacturing method thereof having advantages of minimizing the inductor area in a high frequency circuit.

Accordingly, the present invention may have advantages of reducing parasitic capacitance that may be caused by a large-sized inductor.

Further consistent with the present invention, there is provided a semiconductor device and a manufacturing method thereof having advantages of high inductance in a limited area of a high frequency device. An exemplary semiconductor device consistent with the present invention includes a lower metal line formed on a substrate; a first column portion formed at a first location on the lower metal line, the first column portion including at least one first metal plug and at least one first intermediate metal block, wherein a lowest one of the at least one first metal plug and the at least one first intermediate metal block is connected to the lower metal line; a second column portion formed at a second location on the lower metal line, the second column portion including at least one second metal plug and at least one second intermediate metal block, wherein a lowest one of the at least one second metal plug and the at least one second intermediate metal block is connected with the lower metal line; a third column portion formed at a third location between the first and second locations, the third column portion including at least one third metal plug and at least one third intermediate metal block, wherein the third column portion is separated from the lower metal line; and an upper metal block connecting the third column portion with one of the first and second column portions at a top position thereof.

An exemplary manufacturing method of a semiconductor device consistent with the present invention includes forming a first insulation layer on a substrate; forming a first trench on the substrate by selectively etching the first insulation layer; forming a lower metal line by filling the first trench with a conductive material; forming a second insulation layer on the first insulation layer; selectively etching the second insulation layer at first and second locations forming a plurality of second trenches and a plurality of first contact holes; forming a plurality of intermediate metal blocks by filling the first contact holes and the second trenches with a conductive material; forming a third insulation layer on the second insulation layer and the intermediate metal blocks; selectively etching the third insulation layer so as to form a plurality of second contact holes and a common trench, the common trench interconnecting an adjacent pair of the second contact holes; and forming an upper metal block by filling the plurality of second contact holes and the common trench with a conductive material.

An exemplary semiconductor device consistent with the present invention includes a substrate and an inductor formed above the substrate, wherein the inductor includes a plurality of metal plugs and metal blocks, and the inductor is formed to have a vertical spiral profile.

The inductor may include a lower conductive portion, first, second, and third conductive column portions, and an upper conductive portion, wherein the first and second conductive column portions may be connected with the lower conductive portion, and the third conductive column portion may be connected with one of the first and second conductive portions by the upper conductive portion at a vertical position higher than the lower conductive portion.

The first, second, and third conductive column portions, the lower conductive portion, and the upper conductive portion may be on a same plane with respect to at least one vertical cross-sectional plane.

At least one of the first, second, and third conductive column portions may include at least one metal plug and at least one horizontal metal block.

The vertical accumulation of the at least one metal plug and the at least one horizontal metal block may include a plurality of metal plugs and a plurality of horizontal metal blocks that are alternately arranged.

### BRIEF DESCRIPTION OF THE DRAWINGS

FIG. 1 is a top plan view showing a conventional inductor.

FIG. 2 is a cross-sectional view of a conventional inductor in FIG. 1.

FIG. 3 is a cross-sectional view of an inductor consistent with the present invention.

FIG. 4 is schematic view of an inductor consistent with the present invention.

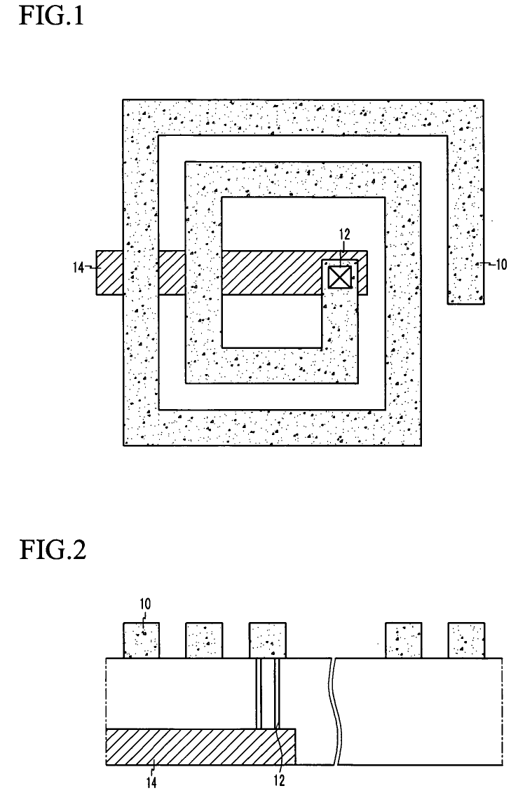

### DETAILED DESCRIPTION

An exemplary embodiment consistent with the present invention will hereinafter be described in detail with reference to the accompanying drawings.

To clarify multiple layers and regions, the thicknesses of the layers are enlarged in the drawings. Like reference numerals designate like elements throughout the specification. When it is said that any part, such as a layer, film, area, or plate is positioned on another part, it means the part may be directly on the other part or above the other part with at least one intermediate part. On the other hand, if any part is said to be positioned directly on another part it means that there is no intermediate part between the two parts.

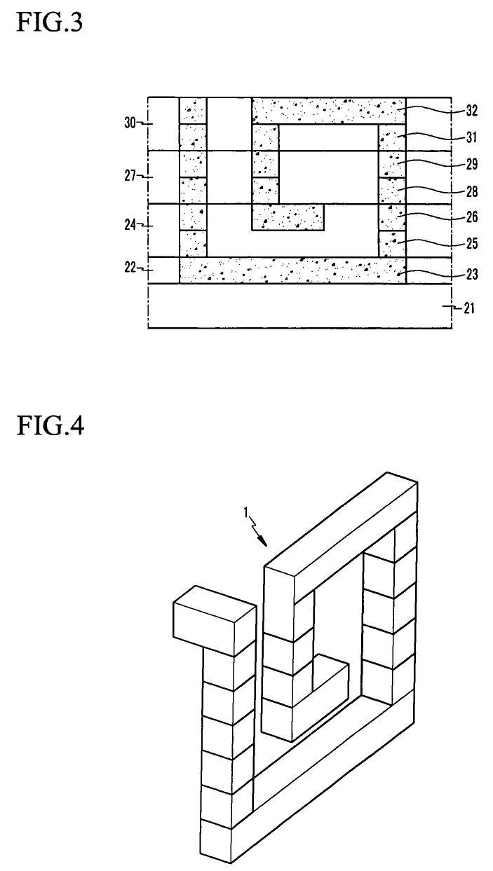

FIG. 3 is a cross-sectional view of an inductor consistent with the present invention, and FIG. 4 is a schematic view of an inductor consistent with the present invention.

Referring to FIG. 3 and FIG. 4, in a manufacturing method of a semiconductor device consistent with the present invention, a first insulation layer 22 is formed on a substrate 21. The first insulation layer 22 is selectively etched so as to form a trench. Subsequently, a conductive material such as copper (Cu) is deposited on the first insulation layer, filling the trench and covering an exposed portion of substrate 21 and is planarized by chemical mechanical polishing (CMP) so as to form a first metal layer 23.

Substrate 21 may be provided with various devices, and isolation regions such as shallow trench isolation (STI) may be formed to electrically isolate the various devices.

Consistent with the present invention, first metal layer 23 is formed on an isolation region, so an inductor can be formed on the isolation region to minimize the parasitic capacitance between the inductor and the various devices on the substrate 21.

The sequential process including selectively etching the first insulation layer 22 so as to form a trench, depositing a conductive material thereon, and planarizing, is called a damascene process. Such a damascene process will be described in detail hereinafter.

Generally, because aluminum is widely available and has low contact resistance, it is often used as a wiring metal in semiconductor chips. However, as semiconductor chips have been more highly integrated, some characteristics associated with using aluminum, such as a junction spike, electro-migration, and relatively high resistivity can be drawbacks in a high integration semiconductor device. Accordingly, it is beneficial to use a metal other than aluminum for forming a wiring in a high integration semiconductor device.

For example, copper has low resistivity and exhibits no electro-migration, and has been recently used to form metal wiring. Copper has a drawback, however, in that it diffuses into silicon layers or most metal layers, so general photolithography and etching processes cannot be used in patterning a copper layer, thus requiring a damascene patterning process.

The damascene process is a copper-metallization process that includes forming a trench region by patterning an insulation layer, depositing copper so as to fill the trench region, and planarizing the copper by a CMP process.

When copper metallization is formed using the damascene process, a dual damascene process that simultaneously forms metal lines and metal plugs is more advantageous in terms of alignment margin and cost than a single damascene process that forms only copper lines.

In the dual damascene process, contact holes and trenches are formed in an insulation layer, so metal lines and metal plugs can be simultaneously formed.

In view of the above description of the damascene and dual damascene processes, referring again to FIG. 3, a second insulation layer 24 is subsequently formed on first insulation layer 22 provided with the first metal layer 23 and is selectively etched so as to form a plurality of contact holes exposing a pair of edge portions of the first metal layer 23. In addition, a plurality of trenches are formed in the second insulation layer 24 by selectively etching, wherein two of the trenches are formed on the contact holes and one of the trenches is formed above a middle portion of the lower metal line 23. When the contact holes and trenches have equal width, first metal plugs 25 and second metal layers 26 may also have equal width, minimizing the resistivity of the inductor.

Although not shown in FIGS. 3 and 4, a barrier metal may be formed on the entire surface of the resultant structure, and with the barrier metal on sidewalls of the contact holes and trenches in second insulation layer 24 and on the surface of the second insulation layer, the barrier metal formed on the bottom surface of the contact holes is selectively removed.

Subsequently, a conductive material such as copper is deposited on the entire upper surface of second insulating layer 24 and in the contact holes and trenches in second insulation layer 24 and is planarized by chemical mechanical polishing. A pair of stacking structures including the first metal plugs 25 and the second metal layers 26 are formed to be connected with a pair of edge portions of the first metal layer 23. In addition, second metal layers 26 above a middle portion of the first metal layer 23 are separated from the first metal layer 23 by the second insulation layer 24. The second metal layer 26 that is formed above the middle portion of the first metal layer 23 and separated from the first metal layer 23 will be a signal input/output part of an inductor.

A third insulation layer 27 is then formed on the entire upper surface of the resultant structure and is selectively etched so as to form a plurality of contact holes and trenches exposing the second metal layers 26. After a barrier metal (not shown) is formed on the entire upper surface of the resultant structure, the barrier metal formed on the bottom surface of the contact holes is selectively removed.

A conductive material such as copper is deposited on the entire upper surface of third insulation layer 27 and in the contact holes and trenches in third insulation layer 27, and is planarized by chemical mechanical polishing. Three stacking structures including second metal plugs 28 and third metal layers 29 are formed to be connected with of edge portions of the second metal layers 26.

A fourth insulation layer 30 is subsequently formed on the entire upper surface of the resultant structure and is selectively etched so as to form a plurality of contact holes and trenches exposing the third metal layers 29. At this time, one of the trenches connects two neighboring contact holes forming a common trench. After a barrier metal (not shown) is formed on the entire upper surface of the resultant structure, the barrier metal formed on the bottom surface of the contact holes is selectively removed.

A conductive material such as copper is deposited on the entire upper surface of fourth insulation layer 30 and the contact holes and trenches in the fourth insulation layers 30, and is planarized by chemical mechanical polishing. Stacking structures including a third metal plug 31 and a fourth metal layer 32 are formed, and the fourth metal layer 32 in the common trench connects two neighboring contacts of the third metal plug 31. The portion of the fourth metal layer 32 that is not formed in the common trench will be the other signal input/output part of an inductor.

An exemplary semiconductor device and a manufacturing method thereof consistent with the present invention as described above have advantages of minimizing the inductor area in a high frequency circuit by forming an inductor with a vertical spiral geometry. Also, the area overlap between the inductor and various other devices on a substrate may be minimized.

In addition, the damascene process for forming copper metallization may reduce the resistance of the inductor compared with an inductor formed from aluminum or tungsten.

In forming metal layers, because the process windows in the vertical and horizontal direction are wide, inductors having various inductances can be formed. Particularly, when the width, length, and height of the metal layer are adequately designed, an inductor having high inductance can be formed.

Referring again to FIG. 3 and FIG. 4, while four metal layers are adequately connected so as to form the inductor, it is to be understood that the inductor may be formed using three metal layers or five or more metal layers.

In addition, a plurality of inductors formed consistent with the present invention may be connected so as to have a predetermined inductance.

An exemplary semiconductor device and a manufacturing method thereof consistent with the present invention as described above has the advantages of minimizing the inductor area in a high frequency circuit by forming an inductor having a vertical spiral geometry allowing high integration. In addition, the overlapping of the inductor area and various devices formed on a substrate can be minimized preventing the deterioration of the electrical characteristics of the inductor.

The damascene process for forming metallization may further reduce the resistance of the inductor compared with inductors formed from aluminum or tungsten, thereby enhancing the electrical characteristics of the inductor.

Furthermore, the process windows in the vertical and horizontal directions for forming metal layers are wide, allowing the formation of inductors having various inductances. In particular the adequate design of the width, length, and height of the metal layer allows the formation of an inductor having a high inductance.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device, comprising:
a lower metal line formed on a substrate;
a first column portion formed at a first location on the lower metal line, the first column portion comprising at least one first metal plug and at least one first intermediate metal block, wherein a lowest one of the at least one first metal plug and the at least one first intermediate metal block is connected to the lower metal line;
a second column portion formed at a second location on the lower metal line, the second column portion comprising at least one second metal plug and at least one second intermediate metal block, wherein a lowest one of the at least one second metal plug and the at least one second intermediate metal block is connected with the lower metal line;
a third column portion formed at a third location between the first and second locations, the third column portion comprising at least one third metal plug and at least one third intermediate metal block, wherein the third column portion is separated from the lower metal line; and
an upper metal block connecting the third column portion with one of the first and second column portions at a top position thereof.

2. The semiconductor device of claim 1, wherein the lower metal line, the first, second, and third intermediate metal blocks, and the upper metal block comprise copper.

3. The semiconductor device of claim 1, wherein the first, second, and third metal plugs comprise copper.

4. The semiconductor device of claim 1, wherein the lower metal line, the first, second, and third intermediate metal blocks, and the upper metal blocks have the same width as the metal plugs.

5. The semiconductor device of claim 1, wherein the lower metal line is formed in an isolation region on a substrate.

6. A manufacturing method of a semiconductor device, comprising:
forming a first insulation layer on a substrate;
forming a first trench on the substrate by selectively etching the first insulation layer;
forming a lower metal line by filling the first trench with a conductive material;
forming a second insulation layer on the first insulation layer;
selectively etching the second insulation layer at first and second locations forming a plurality of second trenches and a plurality of first contact holes;
forming a plurality of intermediate metal blocks by filling the first contact holes and the second trenches with a conductive material;
forming a third insulation layer on the second insulation layer and the intermediate metal blocks;
selectively etching the third insulation layer so as to form a plurality of second contact holes and a common trench, the common trench interconnecting an adjacent pair of the second contact holes; and
forming an upper metal block by filling the plurality of second contact holes and the common trench with a conductive material.

7. The manufacturing method of claim 6, further comprising, after forming intermediate metal blocks:
forming a fourth insulation layer on the second insulation layer;
forming a plurality of third contact holes by selectively etching the fourth insulation layer;
forming a plurality of third trenches in the fourth insulation layer; and
forming metal blocks by filling the third contact holes and the third trenches with a conductive material.

8. The manufacturing method of claim 6, wherein:
forming the lower metal line, comprises forming the lower metal line by depositing a copper metal layer on the first insulation layer and filling the first trench, and planarizing the copper metal layer;
forming the intermediate metal blocks comprises forming the intermediate metal blocks by depositing a copper metal layer on the second insulation layer and filling the plurality of first contact holes and the plurality of second trenches, and planarizing the copper metal layer;
forming the upper metal blocks comprises forming the upper metal blocks by depositing a copper metal layer on the third insulation layer and filling the plurality of second contact holes and the common trench, and planarizing the copper metal layer.

9. The manufacturing method of claim 6, further comprising:
before forming the lower metal line, forming a barrier metal on the first insulation layer filling the first trench and selectively etching barrier metal formed directly on a bottom surface of the first trench;
before forming the intermediate metal blocks, forming a barrier metal on the second insulation layer, filling the plurality of first contact holes and the plurality of second trenches, selectively etching barrier metal formed directly on a bottom surface of the plurality of first contact holes and the plurality of second trenches; and
before forming the upper metal block, forming a barrier metal on the third insulation layer, filling the plurality of second contact holes and the common trench, and selectively etching barrier metal formed directly on a bottom surface of the plurality of second contact holes and the common trench.

10. A semiconductor device comprising a substrate and an inductor formed above the substrate, wherein:
the inductor comprises a plurality of metal plugs and metal blocks; and
the inductor is formed to have a vertical spiral profile.

11. The semiconductor device of claim 10, wherein the inductor comprises a lower conductive portion, first, second, and third conductive column portions, and an upper conductive portion, and
wherein the first and second conductive column portions are connected with the lower conductive portion, and the third conductive column portion is connected with one of the first and second conductive portions by the upper conductive portion at a vertical position higher than the lower conductive portion.

12. The semiconductor device of claim 11, wherein the first, second, and third conductive column portions, the lower conductive portion, and the upper conductive portion are on a same plane with respect to at least one vertical cross-sectional plane.

13. The semiconductor device of claim 11, wherein at least one of the first, second, and third conductive column portions comprises at least one metal plug and at least one horizontal metal block.

14. The semiconductor device of claim 13, wherein the at least one metal plug and the at least one horizontal metal block comprises a plurality of metal plugs and a plurality of horizontal metal blocks that are alternately arranged.
